(19) United States
(12) Patent Application Publication
(10) Pub. No.: US 2013/0163153 A1
(43) Pub. Date: Jun. 27, 2013

(54) ELECTRONIC DEVICE HAVING PROTECTING COVER

(71) Applicants: YUAN-MING WANG, Shenzhen City (CN); NA WANG, Shenzhen City (CN); YONG-JUN YU, Shenzhen City (CN); RUI LI, Shenzhen City (CN)

(72) Inventors: YUAN-MING WANG, Shenzhen City (CN); NA WANG, Shenzhen City (CN); YONG-JUN YU, Shenzhen City (CN); RUI LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 13/482,417

(22) Filed: May 29, 2012

(30) Foreign Application Priority Data
Dec. 21, 2011 (CN) 201110432407.8

(51) Int. Cl. H05K 5/03

(52) U.S. Cl. 361/679.01

(57) ABSTRACT

An electronic device includes a top case, a bottom case corresponds to the top case, an illuminating unit arranged between the top case and the bottom case, and a protecting cover secured to the top case. The protecting cover allows light emitted by the illuminating unit to be transmitted therethrough. An abutting assembly is secured to an inner surface of the bottom case. The abutting assembly abuts an end of the protecting cover facing the bottom case to secure the protecting cover to the top case when the top case is secured to the bottom case. A housing of an electronic device is also provided.

### BACKGROUND

1. Technical Field

The present disclosure relates to electronic devices, and particularly to an electronic device having a protecting cover.

2. Description of Related Art

Electronic device, such as a DVD player, includes a housing, an illuminating unit housed in the housing, and a transparent protecting cover secured to the housing and corresponding to the illuminating unit. The protecting cover includes a hook member. The housing defines an opening for allowing the protecting cover to be received therein, and includes a latching member arranged adjacent to the opening. The latching member corresponds to the hook member and hooks the hook member to secure the protecting cover to the housing. However, if the protecting cover is made of polymethyl methacrylate, which is very brittle, the protecting cover may be broken when being secured to the housing by the hook member engaging with the latching member.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the three views.

FIG. 1 is a perspective view of an electronic device having a protecting cover in accordance with an embodiment.

FIG. 2 is a partially disassembled perspective view of the electronic device of FIG. 1.

FIG. 3 is a cross-sectional view of the electronic device taken along line III-III in FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

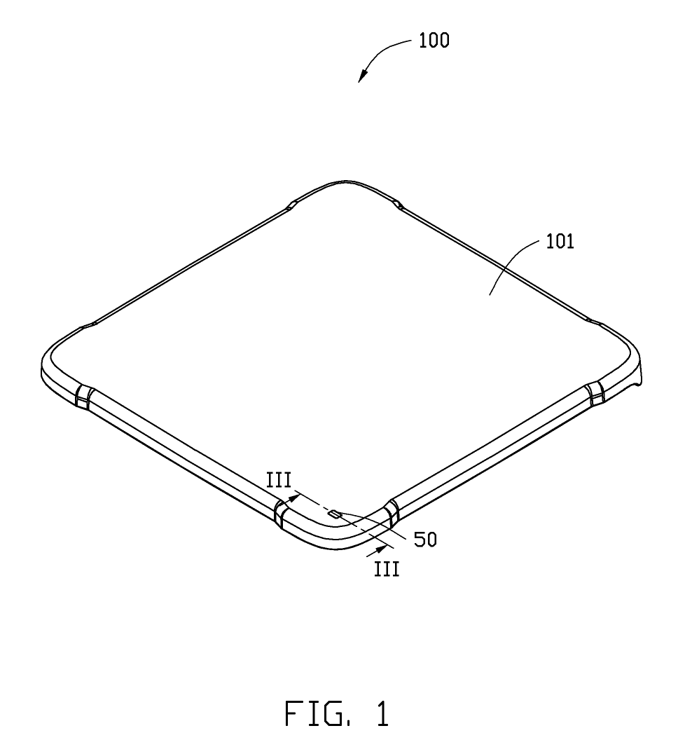

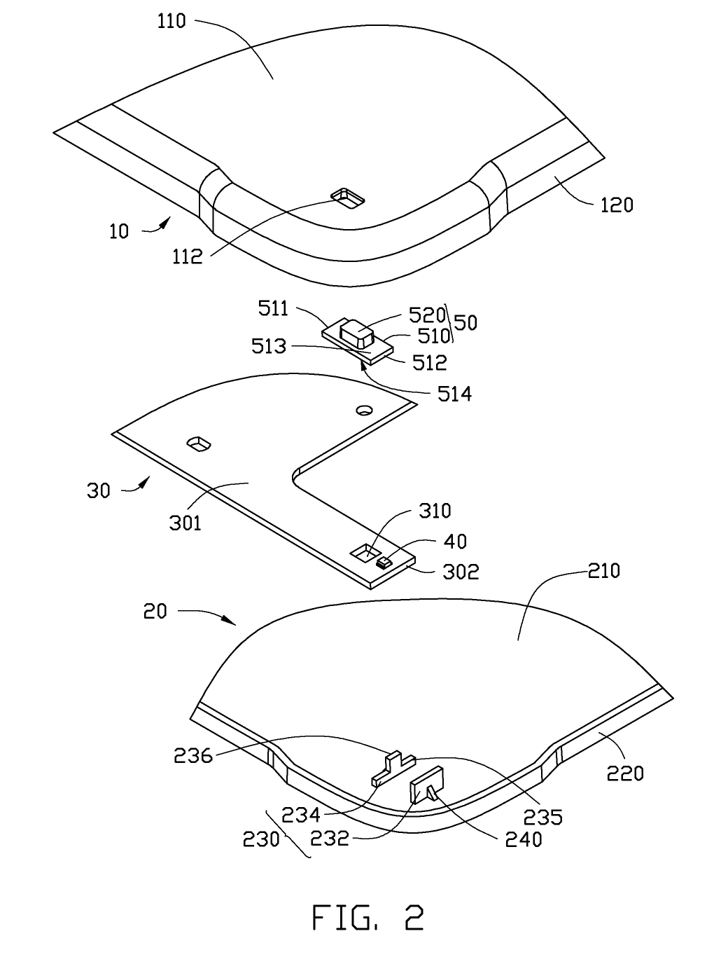

Referring to FIGS. 1-2, an electronic device 100 having a protecting cover 50 is shown. The electronic device 100 includes a housing 101, a circuit board 30 received in the housing 101, an illuminating unit 40 arranged on the circuit board 30, and a protecting cover 50 secured to the housing 101 and corresponding to the illuminating unit 40. The illuminating unit 40 is used for emitting light. In the embodiment, the illuminating unit 40 functions as an indicator for showing the operating condition of the electronic device 100.

The protecting cover 50 is used for allowing light emitted by the illuminating unit 40 to be transmitted therethrough. The protecting cover 50 includes a base 510 and a window 520 arranged on the base 510. The base 510 is substantially rectangular, and includes a first end 511 and a second end 512 opposite to the first end 511. In the embodiment, the window 520 is arranged at the middle of the base 510. When viewed from a front surface 513 of the base 510, the window 520 protrudes out of the front surface 513 of the base 510; When viewed from a rear surface 514 of the base 510, the window 520 is recessed in the rear surface 514 of the base 510. In the embodiment, the protecting cover 50 is made of polymethyl methacrylate and is substantially transparent.

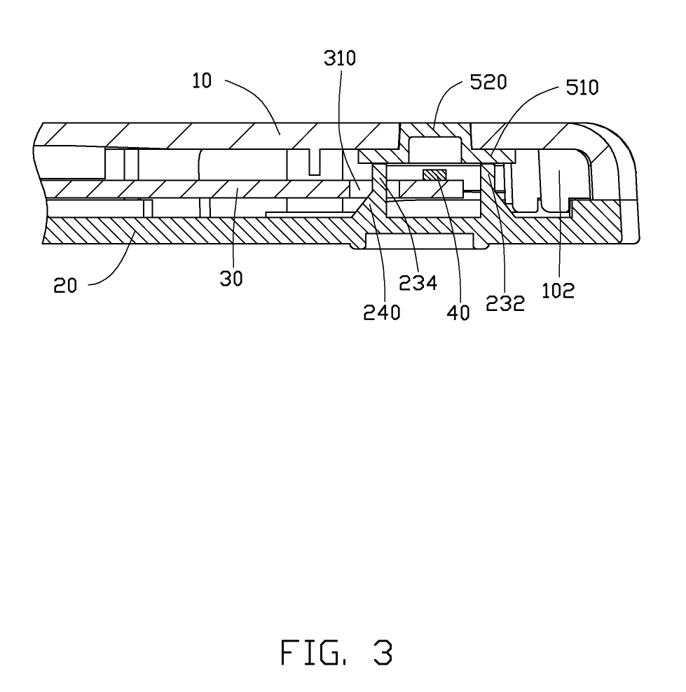

The housing 101 is substantially rectangular, and includes a top case 10 and a bottom case 20. The top case 10 engages with the bottom case 20 to define a receiving space 102 (see FIG. 3) for receiving the circuit board 30, the illuminating unit 40, and other components (not shown) of the electronic device 100.

The top case 10 includes a top wall 110 and four sidewalls extending from the edges of the top wall 120. The top wall 110 is substantially rectangular, and defines an opening 112. The opening 112 is used for receiving the window 520 and allows the window 520 to be exposed out of the housing 101. The size of the opening 112 is smaller than the size of the base 510, but is larger than the size of the window 520. In the embodiment, the opening 112 is substantially rectangular, and is arranged adjacent to a vertex of the top wall 110.

The bottom case 20 includes a bottom wall 210 corresponding to the top wall 110 and four side portions 220 extending from rims of the bottom wall 210. The four side portions 220 correspond to the four sidewalls 120. An abutting assembly 230 is secured to an inner surface of the bottom wall 210 and corresponds to the opening 112. The abutting assembly 230 includes a first abutting member 232 and a second abutting member 234. The first abutting member 232 is parallel to and spaced from the second abutting member 234. A distance between the first and second abutting members 232, 234 is less than the distance between the first and second ends 511, 512. In the embodiment, the first abutting member 232 is substantially rectangular and perpendicular to the bottom wall 210, the second abutting member 234 is substantially T shaped. The second abutting member 234 includes a connecting portion 235 perpendicularly extending from the bottom wall 210 and a resisting portion 236 arranged at an end of the bottom wall 210 away from the bottom wall 210. A rib 240 protrudes form the bottom wall 210 and connects with an end of the first abutting member 232 opposite to the second abutting member 234. The rib 240 is used to enhance the stiffness of the first abutting member 232.

The illuminating unit 40 is arranged adjacent to a side portion 302 of the circuit board 30 and corresponds to the opening 112. The circuit board 30 defines a through hole 310, and the illuminating unit 40 is arranged between the through hole 310 and the side portion 302. The distance between the through hole 310 and the end portion 302 is greater than the distance between the first and second abutting member 232, 234, such that the resisting portion 236 passes through the hole 310, and the first abutting member 232 abuts the end portion 302 of the circuit board 30.

Referring to FIG. 3, in assembly, firstly, the window 520 is received in the opening 112, and the front surface 513 abuts the inner surface of the top wall 110. Secondly, the circuit board 30 is secured to the top case 10 with the illuminating unit 40 corresponding to the window 520. Finally, the bottom case 20 is secured to the top case 10 with the resisting portion 236 passing through the hole 310 and the first abutting member 232 abutting the end portion 302 of the circuit board 30, and the first and second abutting members 232, 234 further abut the rear surface 514 of the base 510. As the widow 520 is received in the opening 112 and the first and second abutting members 232, 234 abut the rear surface 514 of the base 510, the protecting cover 50 is stably secured to the housing 101 after the bottom case 10 is secured to the top case 20.

It is to be understood, even though information as to, and advantages of, the present embodiments have been set forth in the foregoing description, together with details of the structures and functions of the present embodiments, the disclosure is illustrative only; and that changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
a top case;
a bottom case corresponds to the top case;
an illuminating unit arranged between the top case and the bottom case; and
a protecting cover secured to the top case for protecting the illuminating unit, and the protecting cover allowing light emitted by the illuminating unit to transmit therethrough;
wherein an abutting assembly is secured on an inner surface of the bottom case, and the abutting assembly abuts an end of the protecting cover facing the bottom case to secure the protecting cover to the top case when the top case is secured to the bottom case.

2. The electronic device of claim 1, wherein the protecting cover comprises a base and a window arranged on the base, the base comprises a first end and a second end opposite to the first end, and the window is arranged between the first and second ends.

3. The electronic device of claim 2, wherein the protecting cover is made of polymethyl methacrylate and is substantially transparent.

4. The electronic device of claim 2, wherein the top case defines an opening for receiving the window.

5. The electronic device of claim 4, wherein the size of the opening is greater than the window.

6. The electronic device of claim 2, wherein the abutting assembly comprises a first abutting member and a second abutting member parallel to and spaced from the first abutting member.

7. The electronic device of claim 6, wherein the distance between the first and second abutting members is less than that of the first and second ends of the base.

8. The electronic device of claim 6, further comprising a circuit board arranged between the top case and the bottom case, wherein the circuit board defines a through hole adjacent to a rim thereof and corresponding to the second abutting member, the illuminating unit is arranged between the rim of the circuit board and the through hole.

9. The electronic device of claim 8, wherein the distance between the through hole and the corresponding rim of the circuit board is less than the distance between the first and second abutting members.

10. A housing of an electronic device for securing a protecting cover of the electronic device, the protecting cover comprising a first end, a second end opposite to the first end, and a window arranged between the first end and the second end, the housing comprising:
a top case defining an opening for receiving the window; and
a bottom case engaging with the top case;
wherein an abutting assembly is secured on an inner surface of the bottom case, and the abutting assembly abuts an end of the protecting cover facing the bottom case to secure the protecting cover to the top case when the top case is secured to the bottom case.

11. The housing of claim 10, wherein the protecting cover is made of polymethyl methacrylate and is substantially transparent.

12. The housing of claim 10, wherein the size of the opening is greater than the window.

13. The housing of claim 10, wherein the abutting assembly comprises a first abutting member and a second abutting member parallel to and spaced from the first abutting member.

14. The housing of claim 13, wherein the distance between the first and second abutting members is less than that of the first and second ends of the base.

15. The housing of claim 13, wherein the electronic device comprises a circuit board arranged between the top case and the bottom case and an illuminating unit arranged on the circuit board and corresponding to the opening, the circuit board defines a through hole adjacent to a rim thereof and corresponding to the second abutting member, the illuminating unit is arranged between the rim of the circuit board and the through hole.

16. The housing of claim 15, wherein the distance between the through hole and the corresponding rim of the circuit board is less than the distance between the first and second abutting members.
